(19) United States
(12) Patent Application Publication
(10) Pub. No.: US 2006/0091531 A1
(43) Pub. Date: May 4, 2006

(54) Cavity-down thermally enhanced package

(76) Inventor: Ching-Hsu Yang, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/262,762

(22) Filed: Nov. 1, 2005

(30) Foreign Application Priority Data
Nov. 3, 2004 (TW) 093133485

(51) Int. Cl. H01L 23/34

(52) U.S. Cl. 257/712

(57) ABSTRACT

A cavity-down thermally enhanced package mainly comprises a heat spreader, a thermally conductive metal ring, a circuit substrate and a chip. The circuit substrate is attached to a receiving surface of the heat spreader, and has an opening for exposing part of the receiving surface. The thermally conductive metal ring and the chip are disposed within the opening. The chip is attached to the receiving surface of the heat spreader, and the thermally conductive metal ring protrudes from the receiving surface of the heat spreader and is located between a side surface of the chip and an inner lateral wall of the circuit substrate, for improving the heat dissipating efficiency and the electrical shielding effect of the chip.

### BACKGROUND OF THE INVENTION

1. Field of the Invention

The present invention relates to a cavity-down package, and more particularly to a cavity-down thermally enhanced package.

2. Description of the Related Art

In the conventional Cavity-Down Ball Grid Array (Cavity-Down BGA) package, a chip is attached to a heat spreader, for enhancing the heat dissipating efficiency of the Cavity-Down BGA package.

Referring to FIG. 1, a conventional cavity-down thermally enhanced package 100 comprises a heat spreader 110, a circuit substrate 120, and a chip 130. The heat spreader 110 has a receiving surface 111 on which the circuit substrate 120 and the chip 130 are disposed. The circuit substrate 120 has an opening 121, which passes through an upper surface 122 and a lower surface 123 of the circuit substrate 120. The receiving surface 111 of the heat spreader 110 has a chip mounting area 11a exposed in the circuit substrate 120. The chip mounting area 11a is defined by the opening 121. A liquid adhesive 140 is formed on the chip mounting area 111a, and adheres the chip 130 to the receiving surface 111 of the heat spreader 110. The chip 130 is electrically connected to the circuit substrate 120 through a plurality of bonding wires 150. A molding compound 160 is formed at the opening 121, for sealing the chip 130 and the bonding wires 150. A plurality of solder balls 170 are formed on the lower surface 123 of the circuit substrate 120 for external electrical connections.

In the above-mentioned conventional cavity-down thermally enhanced package 100, the heat generated by the chip 130 during operation is not easily conducted to the heat spreader 110 by the liquid adhesive 140, due to the poor thermal conductivity of the liquid adhesive 140. In addition, the liquid adhesive 140 tends to flow and adhere to the circuit substrate 120 during chip mounting, thus influences the quality.

Consequently, there is an existing need for a cavity-down thermally enhanced package to solve the above-mentioned problems.

### SUMMARY OF THE INVENTION

The object of the present invention is to provide a cavity-down thermally enhanced package. A chip and a thermally conductive mental ring are disposed within an opening of a circuit substrate. The chip is mounted to a receiving surface of a heat spreader, and the thermally conductive metal ring protrudes from the receiving surface of the heat spreader and is adjacent to at least one side surface of the chip. The thermally conductive meal ring can enhance the electrical shielding effect of the chip, and enlarge the heat dissipating area of the chip, thereby reducing the thermal resistance from the chip to the heat spreader in the prior art, and enhancing the heat dissipating efficiency of the cavity-down thermally enhanced package.

Another object of the present invention is to provide a cavity-down thermally enhanced package. A thermally conductive metal ring is protruded from a receiving surface of a heat spreader, and can be formed integrally with the heat spreader. Alternatively, the thermally conductive metal ring can be attached to the receiving surface of the heat spreader. The enclosed area of the thermally conductive metal ring defines a chip mounting area of the heat spreader, so that a chip attaching material formed in the chip mounting area will not adhere to an inner lateral wall of the circuit substrate.

A cavity-down thermally enhanced package according to the present invention mainly comprises a heat spreader, a thermally conductive metal ring, a circuit substrate, a chip, and a molding compound. The heat spreader has a receiving surface. The circuit substrate is attached to the receiving surface of the heat spreader, and has an opening that exposes part of the receiving surface and at least one inner lateral wall within the opening. The thermally conductive metal ring and the chip are disposed within the opening. The chip has an active surface, a back surface, and a side surface between the active surface and the back surface, wherein the back surface is disposed on the receiving surface of heat spreader. The chip is electrically connected to the circuit substrate, and the molding compound is formed within the opening for sealing the chip and the thermally conductive metal ring. The thermally conductive metal ring protrudes from the receiving surface of the heat spreader, and is located between the side surface of the chip and the inner lateral wall of the circuit substrate, for enhancing the heat dissipating efficiency of the cavity-down thermally enhanced package.

### BRIEF DESCRIPTION OF THE DRAWINGS

FIG. 1 is a schematic cross-sectional view of the conventional cavity-down thermally enhanced package;

FIG. 2 is a schematic cross-sectional view of a cavity-down thermally enhanced package according to the first embodiment of the present invention; and

FIG. 3 is a schematic cross-sectional view of a cavity-down thermally enhanced package according to the second embodiment of the present invention.

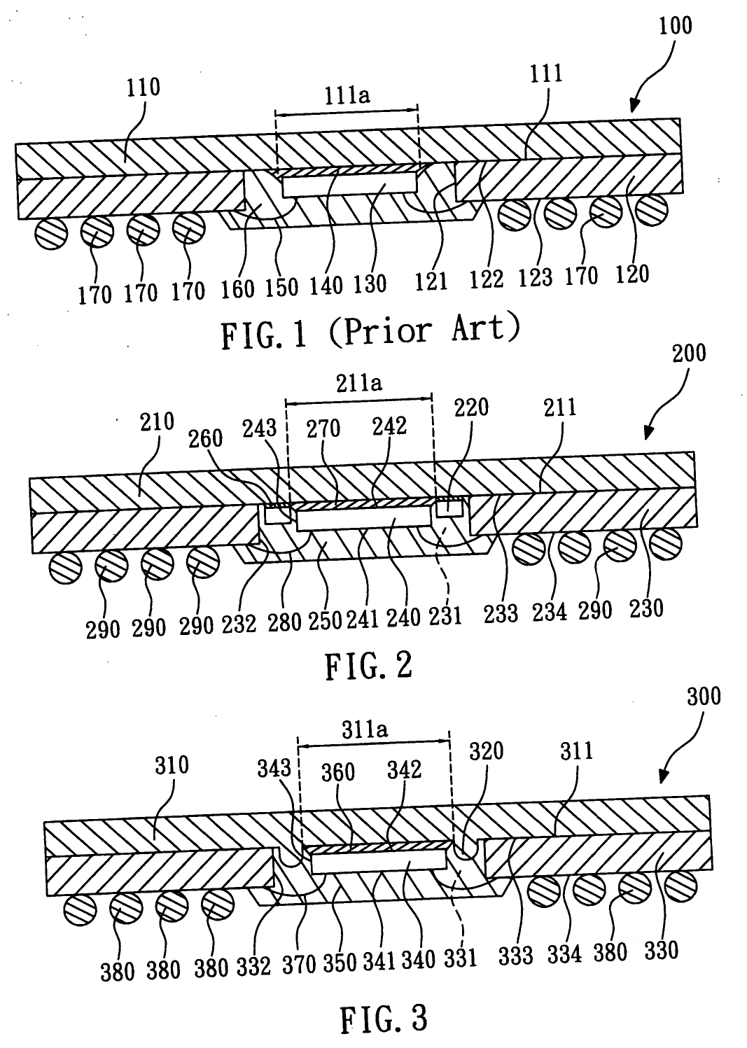

### DETAILED DESCRIPTION OF THE INVENTION

The present invention will be illustrated through the following preferred embodiments, with reference to the accompanying drawings.

Referring to FIG. 2, according to the first embodiment of the present invention, a cavity-down thermally enhanced package 200 mainly comprises a heat spreader 210, a thermally conductive metal ring 220, a circuit substrate 230, a chip 240 and a molding compound 250. The heat spreader 210 has a receiving surface 211. The circuit substrate 230 is attached to the receiving surface 211 of the heat spreader 210, and has an opening 231 and at least one inner lateral wall 232 within the opening 231. The opening 231 exposes part of the receiving surface 211. A chip carrier for the cavity-down thermally enhanced package is defined by the heat spreader 210, the circuit substrate 230 and the thermally conductive metal ring 220. In this embodiment, the opening 231, either round or rectangle shaped, passes through an upper surface 233 and a lower surface 234 of the circuit substrate 230.

The thermally conductive metal ring 220 is disposed within the opening 231, and protrudes from the receiving surface 211 of the heat spreader 210. The thermally conductive metal ring 220 can be formed integrally with the heat spreader 210; or alternatively it can be adhered to the receiving surface 211 of the heat spreader 210 by an adhesive layer. In this embodiment, the thermally conductive metal ring 220 is adhered to the receiving surface 211 of the heat spreader 210 by an adhesive layer 260. In addition, the enclosed area of the thermally conductive metal ring 220 defines a chip mounting area 211a on which the chip 240 is mounted. The cross section of the thermally conductive metal ring 220 is a rectangle, and the material of the thermally conductive metal ring 220 comprises copper, the same as that of the heat spreader 210.

In this embodiment, a chip attaching material 270 is formed within the chip mounting area 211a so as to adhere the chip 240 to the receiving surface 211 of the heat spreader 210. The chip attaching material 270 is a liquid adhesive, and will not overflow to the circuit substrate 230 by the restriction of the thermally conductive metal ring 220.

The chip 240 has an active surface 241, a back surface 242 and a side surface 243 between the active surface 241 and the back surface 242. The chip 240 is disposed within the opening 231, with the back surface 242 attached to the chip mounting area 211a of the receiving surface 211. The active surface 241 is electrically connected to the circuit substrate 230 by a plurality of bonding wires 280.

The molding compound 250 is formed at the opening 231, for sealing the thermally conductive metal ring 220, the chip 240 and the bonding wires 280. In addition, a plurality of solder balls 290 are bonded on the lower surface 234 of the circuit substrate 230 for conducting to outside, which is used for external electrical connection of the cavity-down thermally enhanced package 200.

In the above-mentioned cavity-down thermally enhanced package 200, the thermally conductive metal ring 220 located within the opening 231 protrudes from the receiving surface 211 of the heat spreader 210, and is located between the side surface 243 of the chip 240 and the inner lateral wall 232 of the circuit substrate 230. Thus, the thermally conductive metal ring 220 and the heat spreader 210 provide a good electrical shielding effect for the chip 240. In addition, the thermally conductive metal ring 220 can enlarge the heat dissipating area of the chip 240 so as to enhance the heat dissipating efficiency of the cavity-down thermally enhanced package 200, and reduce the thermal resistance of the chip in the prior art in which the chip is adhered to the heat spreader only by chip attaching materials.

Referring to FIG. 3, according to the second embodiment of the present invention, a cavity-down thermally enhanced package 300 mainly comprises a heat spreader 310, a thermally conductive metal ring 320, a circuit substrate 330, a chip 340 and a molding compound 350. The heat spreader 310 has a receiving surface 311, and the circuit substrate 330 is attached to the receiving surface 311 of the heat spreader 310, wherein the circuit substrate 330 has an opening 331 and at least one inner lateral wall 332 within the opening 331. The opening 331 passes through an upper surface 333 and a lower surface 334 of the circuit substrate 330, so that part of the receiving surface 311 is exposed.

The thermally conductive metal ring 320 protrudes from the receiving surface 311 of the heat spreader 310. In this embodiment, the thermally conductive metal ring 320 is formed integrally with the heat spreader 310, and it is disposed within the opening 331. The enclosed area of the thermally conductive metal ring 320 defines a chip mounting area 311a on which the chip 340 is mounted. The cross-section of the thermally conductive metal ring 320 is an arc.

Thus, a chip attaching material 360 can be formed within the chip mounting area 311a, for adhering the chip 340 to the heat spreader 310.

The chip 340 is disposed within the opening 331, and has an active surface 341, a back surface 342 and a plurality of side surfaces 343 between the active surface 341 and the back surface 342. The back surface 342 of the chip 340 is adhered to the chip mounting area 311a of the heat spreader 310 by the chip attaching material 360, and the active surface 341 is electrically connected to the circuit substrate 330 by a plurality of bonding wires 370.

The molding compound 350 is formed within the opening 331, for sealing the thermally conductive metal ring 320, the chip 340, and the bonding wires 370. A plurality of solder balls 380 is bonded to the lower surface 334 of the circuit substrate 330 for external electrical connections.

In the above-mentioned cavity-down thermally enhanced package 300, the thermally conductive metal ring 320 is located between the side surface 343 of the chip 340 and the inner lateral wall 332 of the circuit substrate 330, and thus the thermally conductive metal ring 320 and the heat spreader 310 can provide a good electrical shielding effect. In addition, the thermally conductive metal ring 320 may enlarge the heat spreading area of the chip 340, for enhancing the heat dissipating efficiency of the cavity-down thermally enhanced package 300.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A cavity-down thermally enhanced package, comprising:
a heat spreader having a receiving surface;
a circuit substrate attached to the receiving surface of the heat spreader, the circuit substrate having an opening and at least one inner lateral wall within the opening, wherein part of the receiving surface of the heat spreader is exposed by the opening;
a chip disposed within the opening, the chip having an active surface, a back surface and a side surface between the active surface and the back surface, wherein the back surface is attached to the exposed receiving surface of the heat spreader, and the chip is electrically connected to the circuit substrate;
a thermally conductive metal ring disposed within the opening, the thermally conductive metal ring protruding from the receiving surface of the heat spreader, and located between the side surface of the chip and the inner lateral wall of the circuit substrate; and
a molding compound formed within the opening, for sealing the chip and the thermally conductive metal ring.

2. The cavity-down thermally enhanced package according to claim 1, wherein the thermally conductive metal ring and the heat spreader are formed integrally.

3. The cavity-down thermally enhanced package according to claim 1, further comprising an adhesive layer that is used for adhering the thermally conductive metal ring to the heat spreader.

4. The cavity-down thermally enhanced package according to claim 1, wherein the cross-section of the thermally conductive metal ring is rectangle.

5. The cavity-down thermally enhanced package according to claim 1, wherein the cross-section of the thermally conductive metal ring is an arc.

6. The cavity-down thermally enhanced package according to claim 1, wherein the material of the thermally conductive metal ring comprises copper.

7. The cavity-down thermally enhanced package according to claim 1, wherein the receiving surface has a chip mounting area, which is defined by the enclosed area of the thermally conductive metal ring.

8. The cavity-down thermally enhanced package according to claim 7, further comprising a chip attaching material which is formed on the chip mounting area and is used for adhering the back surface of the chip to the receiving surface of the heat spreader.

9. The cavity-down thermally enhanced package according to claim 1, further comprising a plurality of solder balls bonded to a lower surface of the circuit substrate.

10. A chip carrier adapted for a cavity-down thermally enhanced package, comprising:
a heat spreader having a receiving surface;
a circuit substrate attached to the receiving surface of the heat spreader, and having an opening and at least one inner lateral wall within the opening, wherein part of the receiving surface of the heat spreader is exposed by the opening; and
a thermally conductive metal ring disposed within the opening, and protruding from the receiving surface of the heat spreader, wherein the thermally conductive metal ring is located between the side surface of the chip and the inner lateral wall of the circuit substrate.

11. The chip carrier adapted for a cavity-down thermally enhanced package according to claim 10, wherein the thermally conductive metal ring and the heat spreader are integrated as a whole.

12. The chip carrier adapted for a cavity-down thermally enhanced package according to claim 10, further comprising an adhesive layer, which is used for adhering the thermally conductive metal ring to the heat spreader.

13. The chip carrier adapted for a cavity-down thermally enhanced package according to claim 10, wherein the cross-section of the thermally conductive metal ring is rectangle.

14. The chip carrier adapted for a cavity-down thermally enhanced package according to claim 10, wherein the cross section of the thermally conductive metal ring is an arc.

15. The chip carrier adapted for a cavity-down thermally enhanced package according to claim 10, wherein the material of the thermally conductive metal ring comprises copper.

16. The chip carrier adapted for a cavity-down thermally enhanced package according to claim 10, wherein the receiving surface has a chip mounting area, which is defined by the enclosed area of the thermally conductive metal ring.
